(19) United States
(12) Patent Application Publication
(10) Pub. No.: US 2026/0196164 A1
(43) Pub. Date: Jul. 9, 2026

(54) PIXEL, DISPLAY DEVICE INCLUDING THE PIXEL, AND ELECTRONIC DEVICE

(71) Applicants: Samsung Display Co., LTD., Yongin-si (KR); University-Industry Cooperation Group of Kyung Hee University, Yongin-si (KR)

(72) Inventors: Ji Young LEE, Yongin-si (KR); Hyoung Sik Nam, Incheon (KR); Hyun Young CHOI, Yongin-si (KR); Hyung Uk CHO, Yongin-si (KR); Hyeon Seong Cho, Seoul (KR); Yeon Hak PYO, Seoul (KR)

(21) Appl. No.: 19/411,870

(22) Filed: Dec. 8, 2025

(30) Foreign Application Priority Data
Jan. 6, 2025 (KR) 10-2025-0001546

(51) Int. Cl. G09G 3/32; G09G 3/3233

(52) U.S. Cl. CPC G09G 3/32; G09G 3/3233; G09G 2300/0426; G09G 2300/0819; G09G 2320/0257; G09G 2330/021

(57) ABSTRACT

A pixel according to embodiments of the present disclosure includes: a light emitting element positioned between a first power line and a second power line; a first transistor connected to the first power line via a first node, connected to the second power line via a second node and the light emitting element, and having a gate electrode connected to a third node; a second transistor connected between a data line and the first node and having a gate electrode connected to a scan line; a third transistor connected between the second node and the third node and having a gate electrode connected to the scan line; and a first capacitor having a first electrode connected to the first node and a second electrode connected to the second node.

This application claims priority to Korean Patent Application No. 10-2025-0001546, filed on Jan. 6, 2025, and all the benefits accruing therefrom under 35 U.S.C. § 119, the content of which in its entirety is herein incorporated by reference.

### BACKGROUND

### 1. Field

The present disclosure relates to a pixel, a display device including the pixel, and an electronic device.

### 2. Description of the Related Art

With the development of information technology, the importance of a display device, which is a connection medium between a user and information, is being highlighted. Accordingly, use of display devices such as, for example, a liquid crystal display device, an organic light emitting display device, and the like is increasing.

A display device may display a certain image using pixels. The pixels store a voltage of the data signal. The pixels may generate light of a certain luminance according to an amount of current flowing from a first driving power source to a second driving power source via the light emitting element.

### SUMMARY

Embodiments supported by the present disclosure provide a pixel applicable to a high-resolution panel, a display device including the pixel, and an electronic device.

According to embodiments of the present disclosure, a pixel includes a light emitting element positioned between a first power line and a second power line; a first transistor connected to the first power line via a first node, connected to the second power line via a second node and the light emitting element, and having a gate electrode connected to a third node; a second transistor connected between a data line and the first node and having a gate electrode connected to a scan line; a third transistor connected between the second node and the third node and having a gate electrode connected to the scan line; and a first capacitor having a first electrode connected to the first node and a second electrode connected to the second node.

In an embodiment, the pixel may further include a fourth transistor connected between the first power line and the first node and having a gate electrode connected to a light emission control line; and a fifth transistor connected between the second node and an anode electrode of the light emitting element and having a gate electrode connected to the light emission control line.

In an embodiment, the second transistor and the third transistor may be set to a turn-on state during a first period of a frame period, and the fourth transistor and the fifth transistor may be set to a turn-off state during the first period.

In an embodiment, the first period may be a first horizontal period.

In an embodiment, the pixel may further include a second capacitor connected between the first power line and the third node.

In an embodiment, the pixel may further include a second capacitor connected between the first power line and the second node.

In an embodiment, the pixel may further include a second capacitor connected between the second node and the second power line.

In an embodiment, the pixel may further include a sixth transistor connected between the second electrode of the first capacitor and the second node and having a gate electrode connected to the scan line; and a seventh transistor connected between the second electrode of the first capacitor and the second power line and having a gate electrode connected to the light emission control line.

In an embodiment, the pixel may further include a second capacitor connected between the first power line and the third node.

In an embodiment, the pixel may further include a second capacitor connected between the first power line and the second node.

In an embodiment, the pixel may further include a second capacitor connected between the second node and the second power line.

According to embodiments of the present disclosure, a display device includes pixels connected to scan lines, data lines, and light emission control lines; a scan driver which drives the scan lines; a light emission driver which drives the light emission control lines; and a data driver which drives the data lines. A pixel among the pixels includes a light emitting element positioned between a first power line and a second power line; a first transistor connected to the first power line via a first node, connected to the second power line via a second node and the light emitting element, and having a gate electrode connected to a third node; a second transistor connected between a data line among the data lines and the first node and having a gate electrode connected to a scan line among the scan lines; a third transistor connected between the second node and the third node and having a gate electrode connected to the scan line; and a first capacitor having a first electrode connected to the first node and a second electrode connected to the second node.

In an embodiment, the pixel may further include a fourth transistor connected between the first power line and the first node and having a gate electrode connected to a light emission control line among the light emission control lines; and a fifth transistor connected between the second node and an anode electrode of the light emitting element and having a gate electrode connected to the light emission control line.

In an embodiment, the scan driver may supply an enable scan signal to the scan line such that the second transistor and the third transistor are turned on during a first period of a frame period, and the light emission driver may supply a disable light emission control signal to the light emission control line such that the fourth transistor and the fifth transistor are turned off during the first period.

In an embodiment, the first period may be a first horizontal period.

In an embodiment, the data driver may supply a data signal to the data line during the first period.

In an embodiment, the pixel may further include a second capacitor connected between the first power line and the third node.

In an embodiment, the pixel may further include a second capacitor connected between the first power line and the second node.

In an embodiment, the pixel may further include a second capacitor connected between the second node and the second power line.

In an embodiment, the pixel may further include a sixth transistor connected between the second electrode of the first capacitor and the second node and having a gate electrode connected to the scan line; and a seventh transistor connected between the second electrode of the first capacitor and the second power line and having a gate electrode connected to the light emission control line.

According to embodiments of the present disclosure, an electronic device includes a processor; and a display module which displays an image based on image data supplied from the processor. The display module includes pixels. At least one pixel among the pixels includes a light emitting element positioned between a first power line and a second power line; a first transistor connected to the first power line via a first node, connected to the second power line via a second node and the light emitting element, and having a gate electrode connected to a third node; a second transistor connected between a data line among data lines and the first node and having a gate electrode connected to a scan line among scan lines; a third transistor connected between the second node and the third node and having a gate electrode connected to the scan line; and a first capacitor having a first electrode connected to the first node and a second electrode connected to the second node.

The problems of the present disclosure are not limited to the above-mentioned problems, and other technical problems that are not mentioned may be clearly understood by those skilled in the art from the following description.

A pixel according to embodiments of the present disclosure is connected to a single scan line and a single light emission control line, and does not include a separate power source or line for initializing a driving transistor. Accordingly, the pixel according to embodiments of the present disclosure may be applied to a high-resolution panel.

However, the effects of the present disclosure are not limited to the above-described effects, and may be further expanded in various without departing from spirit and scope of the present disclosure.

### BRIEF DESCRIPTION OF THE DRAWINGS

FIG. 1 is a diagram illustrating a display device according to an embodiment of the present disclosure.

FIG. 2 is a diagram illustrating a pixel according to an embodiment of the present disclosure.

FIG. 3 is a waveform diagram illustrating a method of driving a pixel according to an embodiment of the present disclosure.

FIGS. 4A to 4D are diagrams illustrating an operation process of a pixel corresponding to the driving waveform of FIG. 3.

FIG. 5 is a diagram illustrating a simulation result of driving the pixel illustrated in FIG. 2 using the method of FIG. 3.

FIG. 6 is a diagram illustrating a pixel according to an embodiment of the present

### DISCLOSURE

FIG. 7 is a diagram illustrating a pixel according to an embodiment of the present disclosure.

FIG. 8 is a diagram illustrating a pixel according to an embodiment of the present disclosure.

FIG. 9 is a diagram illustrating a pixel according to an embodiment of the present disclosure.

FIG. 10 is a diagram illustrating a pixel according to an embodiment of the present disclosure.

FIG. 11 is a diagram illustrating a pixel according to an embodiment of the present disclosure.

FIG. 12 is a diagram illustrating a pixel according to an embodiment of the present disclosure.

FIG. 13 is a diagram illustrating an electronic device according to an embodiment of the present disclosure.

FIGS. 14 to 17 are examples diagrams illustrating an electronic device according to various embodiments.

### DETAILED DESCRIPTION

Hereinafter, various embodiments of the present disclosure will be described in detail with reference to the accompanying drawings such that those skilled in the art may easily implement the embodiments. The present disclosure may be implemented in various different forms and is not limited to the embodiments described herein.

In order to clearly explain the present disclosure, parts unrelated to the description are omitted, and the same or similar components are denoted by the same reference numerals throughout the specification. Therefore, the reference numerals described herein may also be used in other drawings.

The expression “the same” in the description may mean “substantially the same”. That is, it may be the same to the extent that a person with ordinary knowledge can understand that they are the same. Other expressions may also be expressions in which “substantially” is omitted.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Some embodiments are described in the accompanying drawings in connection with functional blocks, units, and/or modules. Those skilled in the art will appreciate that such blocks, units, and/or modules are physically implemented by logic circuits, discrete components, microprocessors, hard wire circuits, memory devices, wiring connections, and other electronic circuits. It may be formed using semiconductor-based manufacturing techniques or other manufacturing techniques. In the case of blocks, units, and/or modules implemented by a microprocessor or other similar hardware, they may be programmed and controlled using software to perform various functions discussed in the present disclosure, and optionally driven by firmware and/or software. Each block, unit, and/or module may be implemented by dedicated hardware, or may be implemented by a combination of dedicated hardware that performs some functions and a processor (e.g., one or more programmed microprocessors and related circuits) that performs other functions. In some embodiments, blocks, units, and/or modules may be physically separated into two or more separate blocks, units, or modules that interact within a scope that does not depart from the scope of the inventive concept. In some embodiments, blocks, units, and/or modules may be physically combined into more complex blocks, units, or modules without departing from the scope of the present disclosure.

The “connection” between the two components may mean that both electrical and physical connections are used inclusively, but is not necessarily limited thereto. For example, “connection” used with reference to a circuit diagram may mean an electrical connection, and “connection” using with reference to a cross-sectional view and a plan view may mean a physical connection.

Although the terms first, second, and the like are used to describe various components, these components are not limited by these terms. The terms first, second, and the like are used to distinguish one component from another. Therefore, a first component mentioned herein may also be a second component within the technical idea of the present disclosure.

The present disclosure is not limited to the embodiments disclosed herein, and may be implemented in various forms. Each of the embodiments disclosed herein may be practiced alone or in combination with at least one other embodiment.

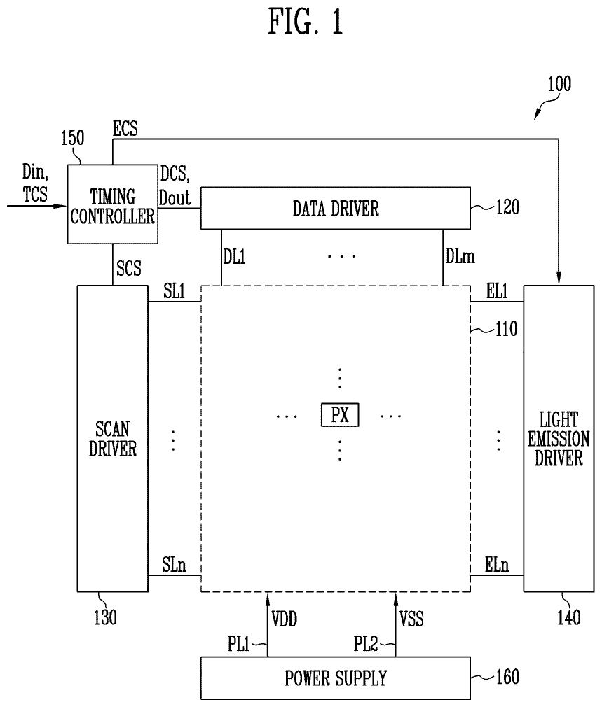

FIG. 1 is a diagram illustrating a display device according to an embodiment of the present disclosure.

Referring to FIG. 1, a display device 100 according to an embodiment of the present disclosure may include a display unit 110 (e.g., a display panel), a data driver 120, a scan driver 130, a light emission driver 140, a timing controller 150, and a power supply 160.

The display unit 110 may include pixels PX connected to scan lines SL1 to SLn, data lines DL1 to DLm, light emission control lines EL1 to ELn, and power lines PL1 and PL2 (wherein n and m are natural numbers of 2 or more).

The pixels PX are selected in units of horizontal lines (for example, pixels connected to the same scan line may form one horizontal line) when an enable scan signal is supplied to the scan lines SL1 to SLn, and the pixels PX selected by the enable scan signal may receive a data signal from a data line (any of DL1 through DLm) connected thereto. The pixels PX supplied with the data signal may generate light of a predetermined luminance in response to the voltage of the data signal.

The scan driver 130 may receive a scan driving signal SCS from the timing controller 150. The scan driving signal SCS may include at least one start signal and clock signals supportive of driving the scan driver 130. The scan driver 130 may generate an enable scan signal while shifting the start signal in response to the clock signals.

A scan signal may include the enable scan signal and a disable scan signal. The enable scan signal may have a gate-on voltage, and the disable scan signal may have a gate-off voltage. For example, the enable scan signal supplied to a P-type transistor may have a logic low voltage, and the disable scan signal supplied to the P-type transistor may have a logic high voltage.

The light emission driver 140 may receive a light emission driving signal ECS from the timing controller 150. The light emission driving signal ECS may include at least one start signal and clock signals supportive of driving the light emission driver 140. The light emission driver 140 may generate a disable light emission control signal while shifting the start signal in response to the clock signals.

A light emission control signal may include the enable light emission control signal and a disable light emission control signal. The enable light emission control signal may have a gate-on voltage, and the disable light emission control signal may have a gate-off voltage. For example, the enable light emission control signal supplied to the P-type transistor may have a logic low voltage, and the disable light emission control signal supplied to the P-type transistor may have a logic high voltage.

The data driver 120 may receive output data Dout and a data driving signal DCS from the timing controller 150. The data driving signal DCS may include a sampling signal and/or timing signals supportive of driving the data driver 120. The data driver 120 may generate a data signal based on the data driving signal DCS and the output data Dout. For example, the data driver 120 may generate an analog data signal based on grayscale values of the output data Dout. The data driver 120 may supply the data signal in units of one horizontal period.

The timing controller 150 may receive input data Din and a timing control signal TCS from a host system via an interface. For example, the timing controller 150 may receive the input data Din and the timing control signal TCS from at least one among a Graphics Processing Unit (GPU), a Central Processing Unit (CPU), and an Application Processor (AP) included in the host system. The timing control signal TCS may include various signals including a clock signal.

The timing controller 150 may generate the scan driving signal SCS, the light emission driving signal ECS, and the data driving signal DCS based on the timing control signal TCS. The scan driving signal SCS, the light emission driving signal ECS, and the data driving signal DCS may be supplied to the scan driver 130, the light emission driver 140, and the data driver 120, respectively.

The timing controller 150 may rearrange the input data Din to meet specifications of the display device 100. The timing controller 150 may generate the output data Dout by correcting (or compensating) the input data Din, and supply the output data Dout to the data driver 120. In an embodiment, the timing controller 150 may correct the input data Din in response to an optical measurement result measured in a manufacturing process.

The power supply 160 may generate various powers (or power sources) supportive of driving the display device 100. For example, the power supply 160 may generate a first driving power VDD and a second driving power VSS.

The first driving power VDD may be a power source that supplies a driving current to the pixels PX. The second driving power VSS may be a power source that receives a driving current from the pixels PX. The first driving power VDD may have a higher voltage than the second driving power VSS during a period in which the pixels PX emit light.

The first driving power VDD generated by the power supply 160 may be supplied to a first power line PL1, and the second driving power VSS may be supplied to a second power line PL2. The first power line PL1 and the second power line PL2 may be commonly connected to the pixels PX, but an embodiment of embodiments of the present disclosure are not limited thereto.

In an embodiment, the first power line PL1 may include a plurality of power lines, and the plurality of power lines may be connected to different pixels PX. In an embodiment, the second power line PL2 may include a plurality of power lines, and the plurality of power lines may be connected to different pixels PX.

In an embodiment of the present disclosure, the display device 100 may include a planar display device, a curved display device in which a part of the display unit 110 is bent, a flexible display device in which a part is foldable or bendable, and a stretchable display device in which a part is stretched.

In an embodiment of the present disclosure, the display device 100 may be a device for displaying a moving image or a still image, and may include a portable electronic device such as, for example, a mobile phone, a smart phone, a tablet personal computer (PC), a smart watch, a watch phone, a mobile communication terminal, an electronic notebook, an electronic book, a PMP (Portable Multimedia Player), navigation, a UMPC (Ultra Mobile PC), and the like. In an embodiment of the present disclosure, the display device 100 may include an electronic device such as, for example, a television, a laptop computer, a monitor, a billboard, or Internet of Things (IoT).

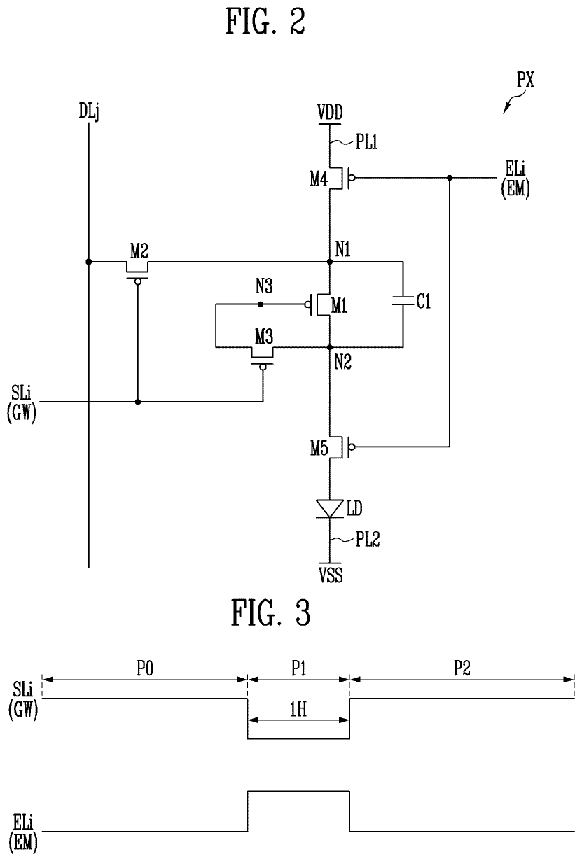

FIG. 2 is a diagram illustrating a pixel according to an embodiment of the present disclosure. In FIG. 2, a pixel PX connected to an i-th scan line SLi (or a scan line) and a j-th data line DLj (or a data line) is illustrated (where i is a natural number of 1 or more and n or less, and j is a natural number of 1 or more and m or less).

Referring to FIG. 2, a pixel PX according to an embodiment of the present disclosure may include a light emitting element LD and a pixel circuit.

The light emitting element LD may be connected between the first power line PL1 and the second power line PL2. For example, the anode electrode of the light emitting element LD may be electrically connected to the first power line PL1 via a first transistor M1 and a fourth transistor M4, and a cathode electrode of the light emitting element LD may be electrically connected to the second power line PL2. The light emitting element LD may generate light of a specific luminance in response to an amount of current supplied from the first power line PL1 to the second power line PL2.

The light emitting element LD may be selected from an organic light emitting diode. The light emitting element LD may also be selected from an inorganic light emitting diode, such as, for example, a micro LED (light emitting diode) or quantum dot light emitting diode. The light emitting element LD may be an element in which an organic material and an inorganic material are combined. Although the pixel PX is illustrated in FIG. 2 as including a single light emitting element LD, in another embodiment, the pixel PX ij includes a plurality of light emitting elements LD, and the plurality of light emitting elements LD may be connected in series, parallel, or in series and parallel to each other.

The pixel circuit may include a first transistor M1, a second transistor M2, a third transistor M3, a fourth transistor M4, a fifth transistor M5, and a first capacitor C1.

A first electrode of the first transistor M1 (or a driving transistor) may be connected to the first power line PL1 via a first node N1, and a second electrode of the first transistor M1 may be connected to the second power line PL2 via a second node N2 and the light emitting element LD. A gate electrode of the first transistor M1 may be connected to a third node N3. The first transistor M1 may control an amount of current flowing from the first power line PL1 to the second power line PL2 via the light emitting element LD in response to a voltage of the third node N3.

The second transistor M2 may be connected between the data line DLj and the first node N1. A gate electrode of the second transistor M2 may be connected to the scan line SLi. The second transistor M2 may may turn on when an enable scan signal GW is supplied to the scan line SLi and may electrically connect the data line DLj and the first node N1.

The third transistor M3 may be connected between the second node N2 and a third node (i.e., the gate electrode of the first transistor M1). A gate electrode of the third transistor M3 may be connected to the scan line SLi. The third transistor M3 may may turn on when the enable scan signal GW is supplied to the scan line SLi and may electrically connect the second node N2 and the third node N3. In an example in which the third transistor M3 is turned on, the first transistor M1 may be diode-connected.

The fourth transistor M4 may be connected between the first power line PL1 and the first node N1. A gate electrode of the fourth transistor M4 may be connected to a light emission control line ELi. The fourth transistor M4 may turn off when the disable light emission control signal EM is supplied, and may may turn on when an enable light emission control signal EM is supplied. In an example in which the fourth transistor M4 is turned off, the first power line PL1 and the first node N1 are electrically disconnected, and thus the pixel PX may not emit light.

The fifth transistor M5 may be connected between the second node N2 and the anode electrode of the light emitting element LD. A gate electrode of the fifth transistor M5 may be connected to the light emission control line ELi. The fifth transistor M5 may turn off when the disable light emission control signal EM is supplied, and may may turn on when the enable light emission control signal EM is supplied. In an example in which the fifth transistor M5 is turned off, the second node N2 and the anode electrode of the light emitting element LD are electrically disconnected, and thus the pixel PX may not emit light.

A first electrode of the first capacitor C1 may be connected to the first node N1, and a second electrode of the first capacitor C1 may be connected to the second node N2. The first capacitor C1 may store a voltage between the first node N1 and the second node N2. The first capacitor C1 may be driven as a coupling capacitor and may control a voltage of the second node N2 in response to a voltage change amount of the first node N1.

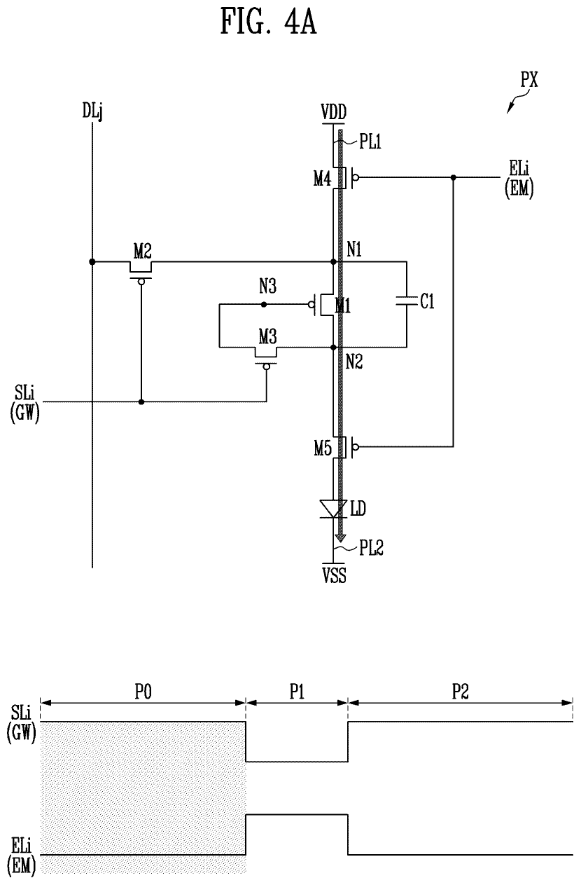

FIG. 3 is a waveform diagram illustrating a method of driving a pixel according to an embodiment of the present disclosure.

In the descriptions of the method and processes herein, the operations may be performed in a different order than the order shown and/or described, or the operations may be performed in different orders or at different times. Certain operations may also be left out, one or more operations may be repeated, or other operations may be added.

Referring to FIG. 3, one frame period may be divided into a zeroth period P0, a first period P1, and a second period P2. The frame period may refer to a duration in which an image frame is displayed in display unit 110. The frame period may also refer to a duration in which the pixel PX receives a data signal corresponding to each image frame and emits light accordingly.

The zeroth period P0 may mean a period in which the pixel PX emits light or does not emit light in response to the data signal supplied in a previous frame period. The first period P1 may mean a period in which the data signal for a current frame period is supplied to the pixel PX. The second period P2 may mean a period in which the pixel PX emits light or does not emit light in response to the data signal supplied to the pixel PX in the first period P1.

The scan driver 130 may supply the enable scan signal GW to the scan line SLi during the first period P1 of the frame period. Here, the first period P1 may mean one horizontal period 1H (e.g., with respect to time).

The data driver 120 may supply the data signal to the data line DLj to be synchronized with the enable scan signal GW during the first period P1.

The light emission driver 140 may supply the disable light emission control signal EM to the light emission control line ELi to overlap the enable scan signal GW during the first period P1.

The terms “enable light emission control signal EM” and “disable light emission control signal EM” may refer to states in which the light emission control signal EM has a voltage which, when applied to a transistor described herein, activate the transistor (e.g., turn “ON” the transistor) or deactivate the transistor (e.g., turn “OFF” the transistor) based on transistor type (e.g., P-type, N-type, or the like).

The terms “enable scan signal GW” and “disable scan signal GW” may refer to states in which the enable scan signal GW has a voltage which, when applied to a transistor described herein, may activate the transistor (e.g., turn “ON” the transistor) or deactivate the transistor (e.g., turn “OFF” the transistor) based on transistor type (e.g., P-type, N-type, or the like).

Although FIG. 2 illustrates that the enable scan signal GW and the disable light emission control signal EM completely overlap during the first period P1, embodiments of the present disclosure are not limited thereto. For example, the disable light emission control signal EM supplied to the light emission control line ELi may be supplied during one horizontal period 1H. The enable scan signal GW supplied to the scan line SLi may overlap the disable light emission control signal EM and may have a width smaller than a width of the disable light emission control signal EM. For example, the disable light emission control signal EM supplied to the light emission control line ELi may be supplied before the enable scan signal GW supplied to the scan line SLi, and the supply of the disable light emission control signal EM may be stopped after the enable scan signal GW.

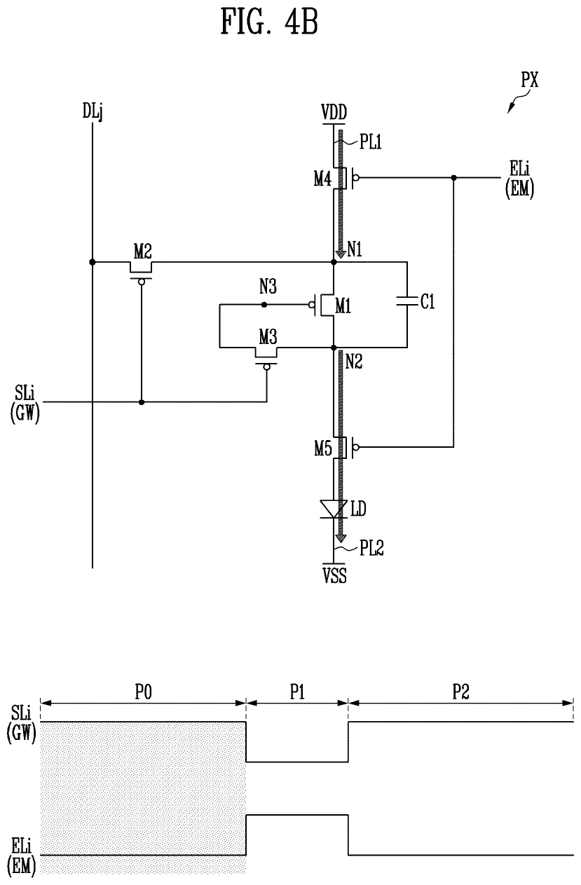

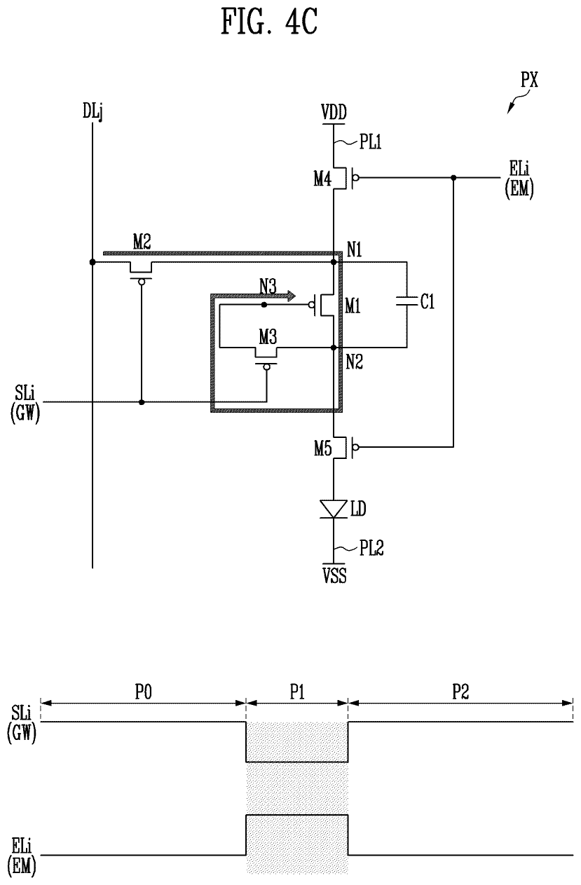

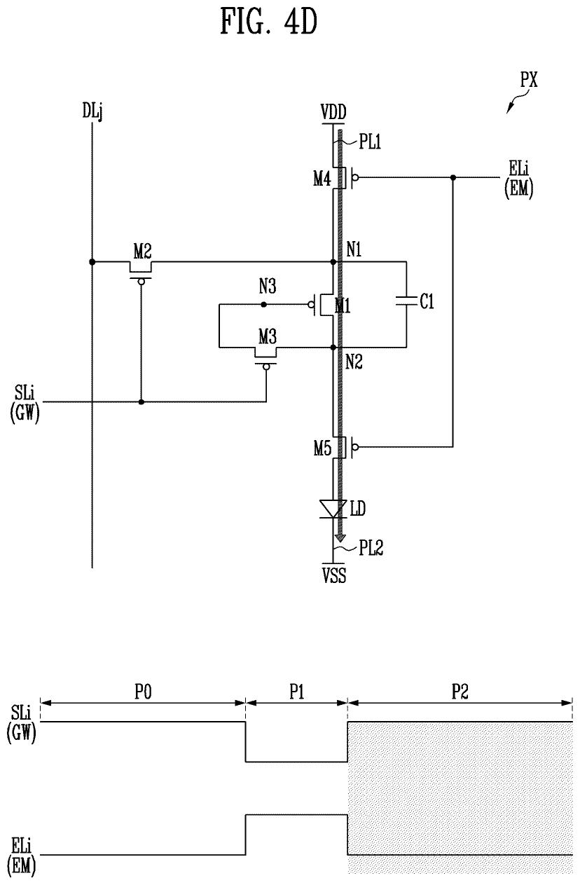

FIGS. 4A to 4D are diagrams illustrating an operation process of a pixel corresponding to the driving waveform of FIG. 3. FIGS. 4A to 4D further illustrate the waveform diagram of FIG. 3, with the shaded areas highlighting periods of the waveform diagram respective to the operation process of the pixel at FIGS. 4A to 4D. FIG. 4A illustrates an example operation of the pixel PX in which the first transistor M1 is turned on during the zeroth period P0 based on the data signal of the previous frame period. FIG. 4B illustrates an example operation of the pixel PX in which the first transistor M1 is turned off during the zeroth period P0 based on the data signal of the previous frame period. Hereinafter, for convenience of description in the examples, the first driving power VDD is 5 V, the second driving power VSS is −4 V, and a threshold voltage of the first transistor M1 is −1.1 V.

Referring to FIG. 4A, during the zeroth period P0, the second transistor M2 and the third transistor M3 may be turned off by a disable scan signal GW, and the fourth transistor M4 and the fifth transistor M5 may be turned on by an enable light emission control signal EM.

In a case in which the fourth transistor M4 and the fifth transistor M5 are turned on, a current path from the first power line PL1 to the second power line PL2 via the light emitting element LD may be formed.

During the zeroth period P0, the first transistor M1 may control the amount of current flowing from the first power line PL1 to the second power line PL2 via the light emitting element LD based on the voltage of the third node N3. In this case, the first node N1 may be set to a voltage (e.g., 5 V) of the first driving power VDD, and the second node N2 may be set to a voltage as in Equation 1.

$$VN 2 = VDD - ( VDD - VSS ) \times \frac{R\_M1on}{( R\_M1on + R\_LD )} \qquad [ Equation 1 ]$$

In Equation 1, R_M1on may mean a turn-on resistance of the first transistor M1 (i.e., a resistance of the first transistor M1 in the turn-on state), and R_LD may mean a resistance of the light emitting element LD. Because the fourth transistor M4 and the fifth transistor M5 are set to the turn-on state, it is assumed in Equation 1 that resistances of the fourth and fifth transistors M4 and M5 are “0”.

In a case in which the turn-on resistance R_LD of the first transistor M1 is assumed to be a low value in Equation 1, the voltage of the second node N2 may be determined corresponding to the resistance of the light emitting element LD.

Referring to FIG. 4B, during the zeroth period P0, the second transistor M2 and the third transistor M3 may be turned off by the disable scan signal GW, and the fourth transistor M4 and the fifth transistor M5 may be turned on by the enable light emission control signal EM.

During the zeroth period P0, the first transistor M1 may be set to a turn-off state. In this case, the first node N1 may be set to a voltage (e.g., 5 V) of the first driving power VDD, and the second node N2 may be set to a voltage as illustrated in Equation 2.

$$\begin{matrix}VN 2 = VDD - ( VDD - VSS ) \times \frac{R\_M1off}{( R\_M1off + R\_LD )} \\ {=}_{.}^{.} VDD - ( VDD - VSS ) \\ {=}_{.}^{.} VSS\end{matrix} \qquad [ Equation 2 ]$$

In Equation 2, R_M1off may mean a turn-off resistance of the first transistor M1 (i.e., a resistance of the first transistor M1 in the turn-off state). In Equation 2, the turn-off resistance of the first transistor M1 may have a higher value than the resistance R_LD of the light emitting element LD. In this case, the voltage of the second node N2 may have approximately a voltage of the second driving power VSS.

Referring to FIG. 4C, during the first period P1, an enable scan signal GW may be supplied to the scan line SLi, and a disable light emission control signal EM may be supplied to the light emission control line ELi.

In a case in which the disable light emission control signal EM is supplied to the light emission control line ELi, the fourth transistor M4 and the fifth transistor M5 may turn off. In a case in which the fourth transistor M4 is turned off, the first power line PL1 and the first node N1 may be electrically disconnected. In a case in which the fifth transistor M5 is turned off, the second node N2 and the anode electrode of the light emitting element LD may be electrically disconnected.

In a case in which the enable scan signal GW is supplied to the scan line SLi, the second transistor M2 and the third transistor M3 may turn on. In a case in which the second transistor M2 is turned on, a data signal from the data line DLj may be supplied to the first node N1. In a case in which the third transistor M3 is turned on, the first transistor M1 may be diode-connected.

In a case in which the first transistor M1 is turned on as illustrated in FIG. 4A, the voltage of the data signal supplied to the first node N1 may be supplied to the second node N2 and the third node N3. Because the first transistor M1 is diode-connected, voltages of the second node N2 and the third node N3 may be set as illustrated in Equation 3.

$$VN 2 ( VN 3 ) = Vdata + Vth \qquad [ Equation 3 ]$$

In Equation 3, Vdata may mean a voltage of the data signal, and Vth may mean the threshold voltage of the first transistor M1. During the first period P1, the first node N1 may have the voltage Vdata of the data signal.

A case in which the first transistor M1 is turned off as illustrated in FIG. 4B will be described as follows. First, the voltage Vdata of the data signal may be supplied to the first node N1 by turning on the second transistor M2. In a case in which the voltage Vdata of the data signal is supplied to the first node N1, the voltage at the first node N1 may change from the voltage of the first driving power VDD to the voltage Vdata of the data signal. Then, the voltage of the second node N2 may also change in response to a voltage change amount of the first node N1 by a coupling of the first capacitor C1.

In this case, the voltages of the second node N2 and the third node N3 may be set as in Equation 4.

$$VN 2 ( VN 3 ) = Vdata - VDD + VSS \qquad [ Equation 4 ]$$

In a case in which the voltage of the third node N3 is set as illustrated in Equation 4, Vgs (a gate-to-source voltage, hereinafter referred to as Vgs voltage) of the first transistor M1 may be set to “Vdata−VDD+VSS−Vdata=−VDD+VSS”. In this case, the Vgs voltage of the first transistor M1 may be set to approximately-9 V, and thus the first transistor M2 may turn on. In a case in which the first transistor M1 is turned on, voltages of the second node N2 and the third node N3 may be set as in Equation 3.

That is, in the pixel PX according to the embodiment of the present disclosure, even if the first transistor M1 is turned off during the previous frame period, the voltage Vdata of the data signal may be supplied to the third node N3 without a separate initialization process. In cast that the gate electrode of the first transistor M1 is not initialized to a separate voltage (e.g., an initialization voltage), the voltage of the data signal may be determined regardless of the initialization voltage. In this case, a voltage range of the data signal may be increased. Referring to FIG. 4D, the second transistor M2 and the third transistor M3 may be turned off by the disable scan signal GW during the second period P2, and the fourth transistor M4 and the fifth transistor M5 may be turned on by the enable light emission control signal EM.

In a case in which the fourth transistor M4 and the fifth transistor M5 are turned on, the first transistor M1 may control the amount of current flowing from the first power line PL1 to the second power line PL2 via the light emitting element LD based on the voltage of the third node N3.

For example, during the second period P2, the Vgs voltage of the first transistor M1 is set to “Vdata+Vth−VDD”, such that a current in which the threshold voltage of the first transistor M1 is compensated may be supplied to the light emitting element LD.

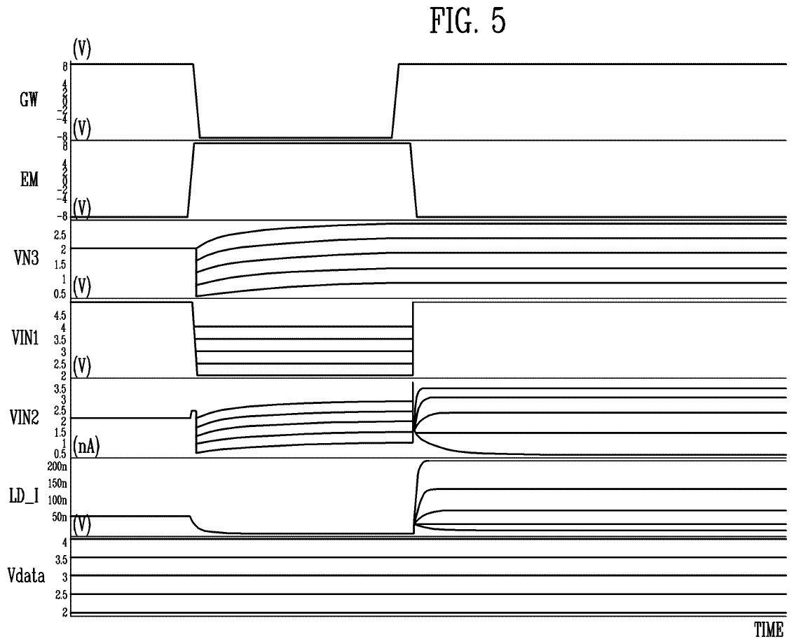

FIG. 5 is a diagram illustrating a simulation result of driving the pixel illustrated in FIG. 2 using the method of FIG. 3. In FIG. 5, LD_I may indicate an amount of current supplied to the light emitting element LD.

Referring to FIG. 5, the amount of current flowing to the light emitting element LD corresponding to the voltage Vdata of the data signal may be illustrated as illustrated in Table 1.

TABLE 1

| | | Vgs [V] | Vgs [V] | |
|---|---|---|---|---|
| Vdata | VN3 [V] | (simulation) | (calculation) | LD_I [nA] |
| 2.0 | 0.93 | −4.07 | −4.10 | 209 |
| 2.5 | 1.41 | −3.59 | −3.60 | 128 |
| 3.0 | 1.91 | −3.10 | −3.10 | 66.7 |
| 3.5 | 2.41 | −2.60 | −2.60 | 29.5 |
| 4.0 | 2.89 | −2.11 | −2.10 | 10.2 |

In Table 1, a Vgs simulation may refer to a Vgs voltage of the first transistor M1 measured as a result of the simulation of the pixel PX, and a Vgs calculation may refer to a Vgs voltage of obtained by calculation.

Referring to Table 1, in a case in which the voltage Vdata of the data signal is set to 2.0 V, 2.5 V, 3.0 V, 3.5 V, or 4.0 V, the voltage of the third node N3 (i.e., a voltage of the gate electrode of the first transistor M1) may be 0.93 V, 1.41 V, 1.91 V, 2.41 V, or 2.89 V, respectively. That is, in the pixel PX according to the embodiment of the present disclosure, the voltage of the third node N3 may change in response to the voltage Vdata of the data signal.

In a case in which the voltage Vdata of the data signal is set to 2.0 V, 2.5 V, 3.0 V, 3.5 V, or 4.0 V, the Vgs voltages of the first transistor M1 obtained by calculation may be −4.10 V, −3.60 V, −3.10 V, −2.60 V, or −2.10 V, respectively, and the Vgs voltages of the first transistor M1 measured as a result of simulation may be −4.07 V, −3.59 V, −3.10 V, −2.60 V, or −2.11 V, respectively. That is, in the embodiment of the present disclosure, the Vgs voltage of the first transistor M1 measured as a result of simulation may be similar to or the same as the Vgs Voltage of the first transistor M1 obtained by calculation.

In a case in which the voltage Vdata of the data signal is set to 2.0 V, 2.5 V, 3.0 V, 3.5 V, or 4.0 V, the amount of current LD_I supplied to the light emitting element LD may be 209 nA, 128 nA, 66.7 nA, 29.5 nA, or 10.2 nA. That is, in the pixel PX according to the embodiment of the present disclosure, the amount of current LD_I flowing to the light emitting element LD may be controlled based on the voltage Vdata of the data signal.

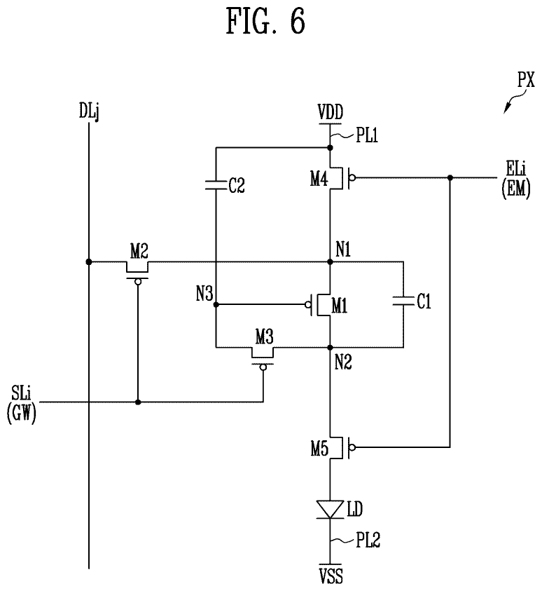

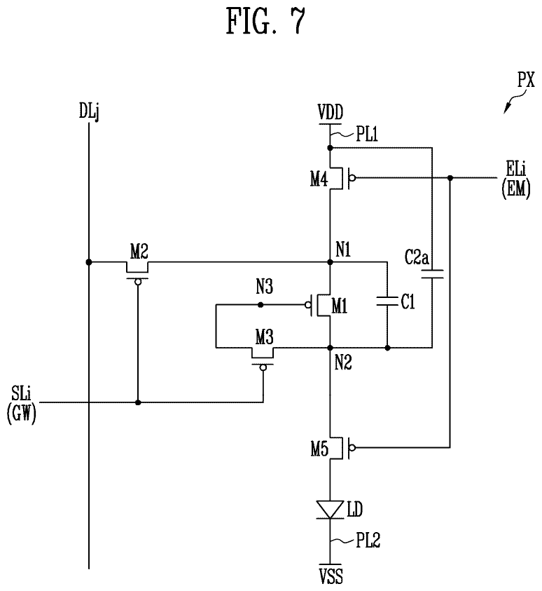

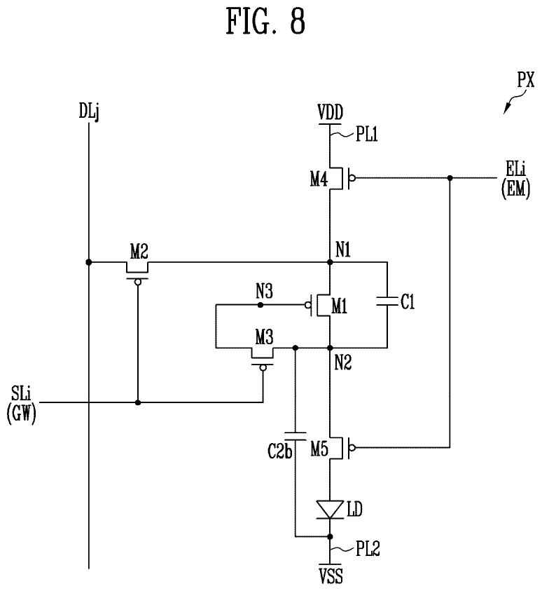

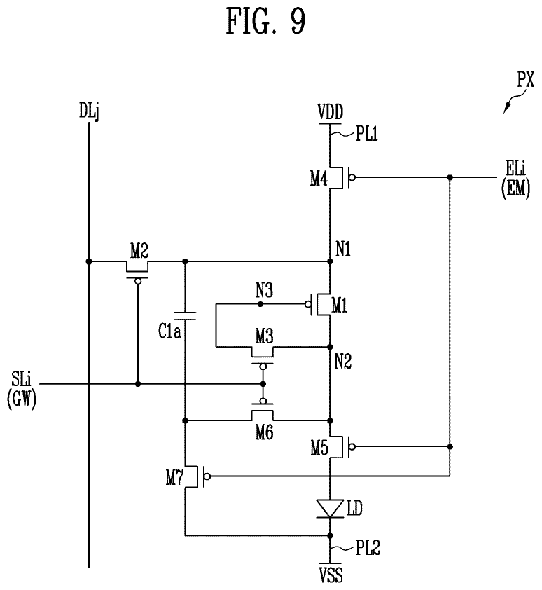

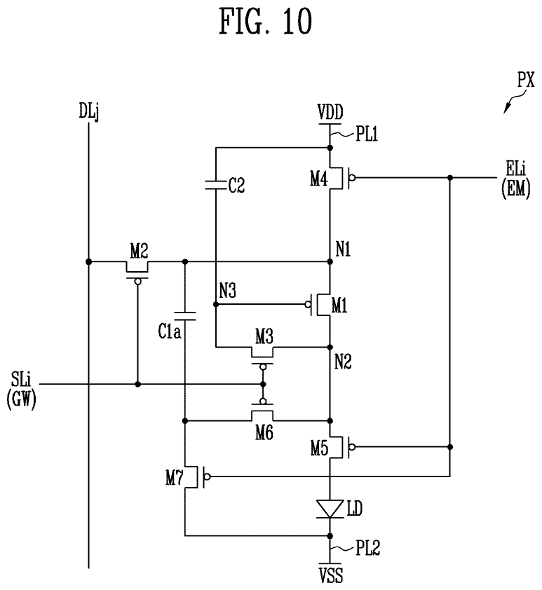

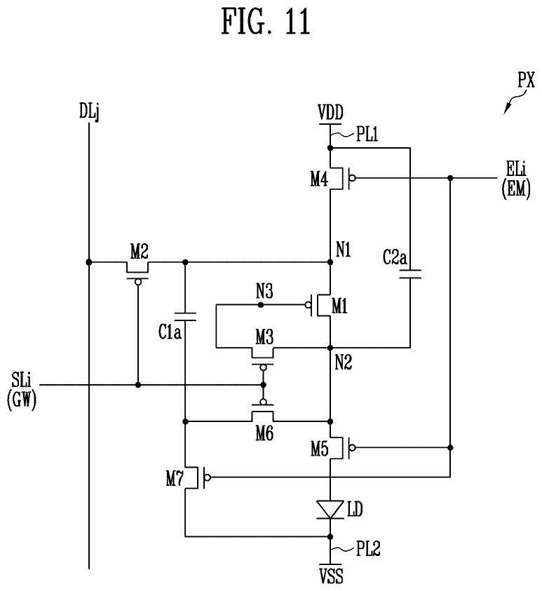

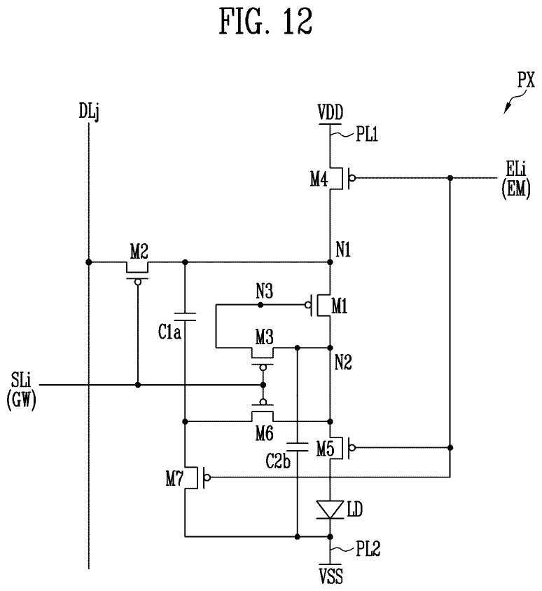

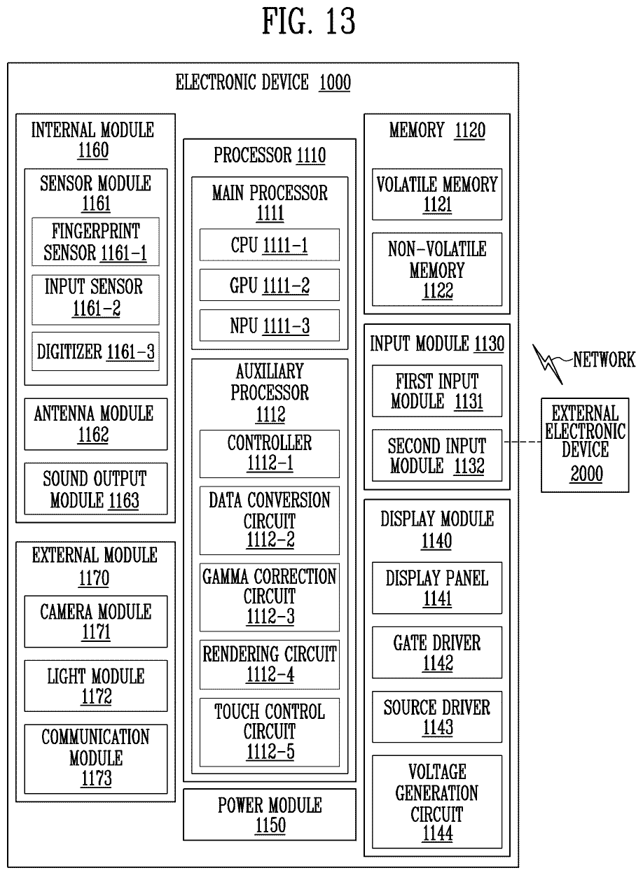

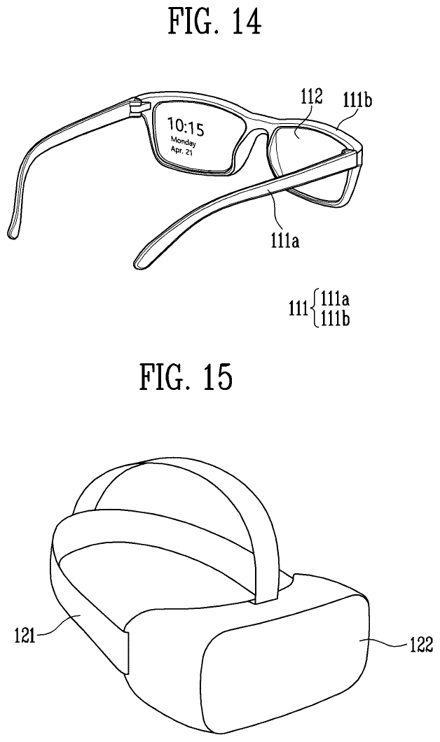

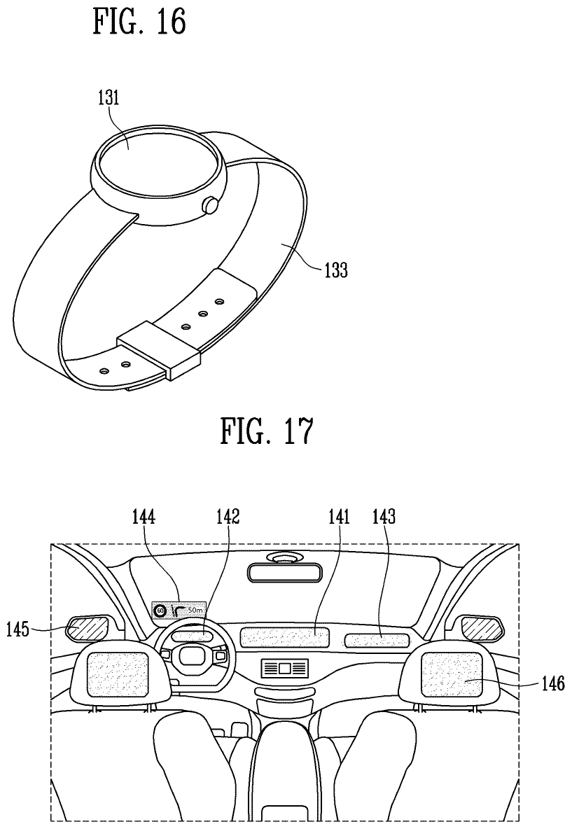

FIG. 6 is a diagram illustrating a pixel according to an embodiment of the present disclosure. In describing FIG. 6, redundant descriptions of the same configuration as those of FIG. 2 will be omitted.

Referring to FIG. 6, the pixel PX according to an embodiment of the present disclosure may include a light emitting element LD and a pixel circuit.

The pixel circuit may include a first transistor M1, a second transistor M2, a third transistor M3, a fourth transistor M4, a fifth transistor M5, a first capacitor C1, and a second capacitor C2.

The second capacitor C2 may be connected between a first power line PL1 and a third node N3. The second capacitor C2 may maintain a voltage of the third node N3 for one frame period.

More specifically, in a case in which the second capacitor C2 is omitted (i.e., in the case of the pixel PX of FIG. 2), the voltage of the third node N3 may be maintained for one frame period by a parasitic capacitor (not illustrated) connected to the third node N3.

In a case in which the second capacitor C2 is added as illustrated in FIG. 6, the voltage of the third node N3 may be maintained by the second capacitor C2 for one frame period.

FIG. 7 is a diagram illustrating a pixel according to an embodiment of the present disclosure. In describing FIG. 7, redundant descriptions of the same configuration as those of FIG. 2 will be omitted.

Referring to FIG. 7, the pixel PX according to an embodiment of the present disclosure may include a light emitting element LD and a pixel circuit.

The pixel circuit may include a first transistor M1, a second transistor M2, a third transistor M3, a fourth transistor M4, a fifth transistor M5, a first capacitor C1, and a second capacitor C2a.

The second capacitor C2a may be connected between a first power line PL1 and a second node N2. The second capacitor C2a may stabilize a voltage of the second node N2 in response to a voltage of the first driving power VDD supplied to a first power line PL1. That is, a voltage fluctuation (or a voltage swing) of the second node N2 may be minimized by the second capacitor C2a.

FIG. 8 is a diagram illustrating a pixel according to an embodiment of the present disclosure. In describing FIG. 8, redundant descriptions of the same configuration as those of FIG. 2 will be omitted.

Referring to FIG. 8, the pixel PX according to an embodiment of the present disclosure may include a light emitting element LD and a pixel circuit.

The pixel circuit may include a first transistor M1, a second transistor M2, a third transistor M3, a fourth transistor M4, a fifth transistor M5, a first capacitor C1, and a second capacitor C2b.

The second capacitor C2b may be connected between a second power line PL2 and a second node N2. The second capacitor C2b may stabilize a voltage of the second node N2 in response to a voltage of the second driving power VSS supplied to a second power line PL2. That is, a voltage fluctuation of the second node N2 may be minimized by the second capacitor C2b.

FIG. 9 is a diagram illustrating a pixel according to an embodiment of the present disclosure. In describing FIG. 9, redundant descriptions of the same configuration as those of FIG. 2 will be omitted.

Referring to FIG. 9, the pixel PX according to an embodiment of the present disclosure may include a light emitting element LD and a pixel circuit.

The pixel circuit may include a first transistor M1, a second transistor M2, a third transistor M3, a fourth transistor M4, a fifth transistor M5, a sixth transistor M6, a seventh transistor M7, and a first capacitor C1a.

A first electrode of the first capacitor C1a may be connected to a first node N1, and a second electrode of the first capacitor C1a may be connected to the second node N2 via the sixth transistor M6. The first capacitor C1a may be driven by the coupling capacitor and may control a voltage of a second node N2 based on a voltage change amount of a first node

N1.

The sixth transistor M6 may be connected between the second electrode of the first capacitor C1a and the second node N2. A gate electrode of the sixth transistor M6 may be connected to a scan line SLi. The sixth transistor M6 may may turn on when an enable scan signal GW is supplied to the scan line SLi and may electrically connect the second electrode of the first capacitor C1a and the second node N2.

The seventh transistor M7 may be connected between the second electrode of the first capacitor C1a and a second power line PL2. A gate electrode of the seventh transistor M7 may be connected to a light emission control line ELi. The seventh transistor M7 may turn off when a disable light emission control signal EM is supplied to the light emission control line ELi and may electrically disconnect the second electrode of the first capacitor C1a and the second power line PL2.

When an operation process is described by combining FIGS. 3 and 9, the second transistor M2, the third transistor M3, and the sixth transistor M6 may be turned off by a disable scan signal GW during the zeroth period P0, and the fourth transistor M4, the fifth transistor M5, and the seventh transistor M7 may be turned on by an enable light emission control signal EM.

In a case in which the seventh transistor M7 is turned on, the second electrode of the first capacitor C1a may be connected to the second power line PL2. In this case, the first node N1 may stably maintain a specific voltage (e.g., a voltage of the first driving power VDD).

In a case in which the fourth transistor M4 and the fifth transistor M5 are turned on, a current path from the first power line PL1 to the second power line PL2 via the light emitting element LD may be formed.

In a case in which the first transistor M1 is set to the turn-on state, during the zeroth period P0, the first transistor M1 may control an amount of current flowing from the first power line PL1 to the second power line PL2 via the light emitting element LD based on a voltage of a third node N3. In this case, the first node N1 may be set to a voltage (e.g., 5 V) of the first driving power VDD, and the second node N2 may be set as in Equation 1.

In a case in which the first transistor M1 is set to the turn-off state, during the zeroth period P0, the first node N1 may be set to a voltage (e.g., 5V) of the first driving power VDD, and the second node N2 may be set as in Equation 2.

During the first period P1, the enable scan signal GW may be supplied to the scan line SLi, and the disable light emission control signal EM may be supplied to the light emission control line ELi.

In a case in which the disable light emission control signal EM is supplied to the light emission control line ELi, the fourth transistor M4, the fifth transistor M5, and the seventh transistor M7 may turn off. In a case in which the fourth transistor M4 is turned off, the first power line PL1 and the first node N1 may be electrically disconnected. In a case in which the fifth transistor M5 is turned off, the second node N2 and the anode electrode of the light emitting element LD may be electrically disconnected. In a case in which the seventh transistor M7 is turned off, the second electrode of the first capacitor C1a and the second power line PL2 may be electrically disconnected.

In a case in which the enable scan signal GW is supplied to the scan line SLi, the second transistor M2, the third transistor M3, and the sixth transistor M6 may turn on.

In a case in which the second transistor M2 is turned on, a data signal from a data line DLj may be supplied to the first node N1. In a case in which the third transistor M3 is turned on, the first transistor M1 may be diode-connected. In a case in which the sixth transistor M6 is turned on, the second electrode of the first capacitor C1a may be electrically connected to the second node N2. In this case, the first capacitor C1a may be connected in the same manner as the first capacitor C1, which is illustrated in FIG. 2.

In a case in which the first transistor M1 is turned on, a voltage Vdata of the data signal supplied to the first node N1 may be supplied to the second node N2 and the third node N3. Here, because the first transistor M1 is diode-connected, voltages of the second node N2 and the third node N3 may be set as illustrated in Equation 3.

In a case in which the first transistor M1 is turned off, a voltage of the second node N2 may be set as illustrated in Equation 4 by the voltage Vdata of the data signal supplied to the first node N1, that is, by coupling of the first capacitor C1a. In a case in which the voltage of the second node N2 is set as in Equation 4, the first transistor M1 may turn on. In a case in which the first transistor M1 is turned on, voltages of the second node N2 and the third node N3 may be set as in Equation 3.

During the second period P2, the second transistor M2, the third transistor M3, and the sixth transistor M6 may be turned off by the disable scan signal GW, and the fourth transistor M4, the fifth transistor M5, and the seventh transistor M7 may be turned on by the enable light emission control signal EM.

In a case in which the fourth transistor M4 and the fifth transistor M5 are turned on, the first transistor M1 may control the amount of current flowing from the first power line PL1 to the second power line PL2 via the light emitting element LD based on the voltage of the third node N3.

As described herein, the pixel PX illustrated in FIG. 9 may be driven in substantially the same manner as the pixel PX illustrated in FIG. 2. However, the second electrode of the first capacitor C1a and the second node N2 may be electrically blocked during the zeroth period P0 and the second period P2 by the sixth transistor M6. The seventh transistor M7 may be electrically connected to the second electrode of the first capacitor C1a and the second power line PL2 during the zeroth period P0 and the second period P2, whereby the voltage of the first node N1 may be stably maintained.

FIG. 10 is a diagram illustrating a pixel according to an embodiment of the present disclosure. In describing FIG. 10, descriptions of the same configurations as those of FIG. 9 will be omitted.

Referring to FIG. 10, the pixel PX according to an embodiment of the present disclosure may include a light emitting element LD and a pixel circuit.

The pixel circuit may include a first transistor M1, a second transistor M2, a third transistor M3, a fourth transistor M4, a fifth transistor M5, a sixth transistor M6, a seventh transistor M7, a first capacitor C1a, and a second capacitor C2.

The second capacitor C2 may be connected between a first power line PL1 and a third node N3. The second capacitor C2 may maintain a voltage of the third node N3 for one frame period.

More specifically, in a case in which the second capacitor C2 is omitted (i.e., in the case of the pixel PX of FIG. 9), the voltage of the third node N3 may be maintained for one frame period by a parasitic capacitor (not illustrated) connected to the third node N3.

In a case in which the second capacitor C2 is added as illustrated in FIG. 10, the voltage of the third node N3 may be maintained by the second capacitor C2 for one frame period.

FIG. 11 is a diagram illustrating a pixel according to an embodiment of the present disclosure. In describing FIG. 11, redundant descriptions of the same configuration as those of FIG. 9 will be omitted.

Referring to FIG. 11, the pixel PX according to an embodiment of the present disclosure may include a light emitting element LD and a pixel circuit.

The pixel circuit may include a first transistor M1, a second transistor M2, a third transistor M3, a fourth transistor M4, a fifth transistor M5, a sixth transistor M6, a seventh transistor M7, a first capacitor C1a, and a second capacitor C2a.

The second capacitor C2a may be connected between a first power line PL1 and a second node N2. The second capacitor C2a may stabilize a voltage of the second node N2 in response to a voltage of a first driving power VDD supplied to the first power line PL1. That is, a voltage fluctuation of the second node N2 may be minimized by the second capacitor C2a.

FIG. 12 is a diagram illustrating a pixel according to an embodiment of the present disclosure. In describing FIG. 12, redundant descriptions of the same configuration as those of FIG. 9 will be omitted.

Referring to FIG. 12, the pixel PX according to an embodiment of the present disclosure may include a light emitting element LD and a pixel circuit.

The pixel circuit may include a first transistor M1, a second transistor M2, a third transistor M3, a fourth transistor M4, a fifth transistor M5, a sixth transistor M6, a seventh transistor M7, a first capacitor C1a, and a second capacitor C2b.

The second capacitor C2b may be connected between a second power line PL2 and a second node N2. The second capacitor C2b may stabilize a voltage of the second node N2 in response to a voltage of a second driving power VSS supplied to the second power line PL2. That is, a voltage fluctuation of the second node N2 may be minimized by the second capacitor C2b.

FIG. 13 is a diagram illustrating an electronic device according to an embodiment of the present disclosure.

Referring to FIG. 13, an electronic device 1000 according to an embodiment of the present disclosure outputs various information through a display module 1140. In an example in which the processor 1110 executes an application stored in a memory 1120, the display module 1140 provides application information to a user through a display panel 1141.

A processor 1110 obtains an external input through an input module 1130 or a sensor module 1161, and executes an application corresponding to the external input. In an example in which the user selects a camera icon (or a camera application icon) displayed on the display panel 1141, the processor 1110 obtains a user input through an input sensor 1161-2 and activates a camera module 1171. The processor 1110 transmits image data corresponding to a captured image acquired through the camera module 1171 to the display module 1140. The display module 1140 may display an image corresponding to the captured image through the display panel 1141.

In another example, when personal information authentication is executed in the display module 1140, a fingerprint sensor 1161-1 acquires input fingerprint information as input data. The processor 1110 compares the input data acquired through the fingerprint sensor 1161-1 with authentication data stored in the memory 1120, and executes an application according to a comparison result. The display module 1140 may display information executed according to a logic of the application through the display panel 1141. The fingerprint sensor 1161-1 may be arranged to acquire fingerprint information in the entire area of the display module 1140 (or the display panel 1141).

In another example, when a music streaming icon displayed on the display module 1140 is selected, the processor 1110 obtains the user input through the input sensor 1161-2 and activates a music streaming application stored in the memory 1120. In an example in which a music execution command is input in the music streaming application, the processor 1110 activates a sound output module 1163 to provide sound information corresponding to the music execution command to the user.

In the foregoing, the operation of the electronic device 1000 has been briefly described. Hereinafter, a configuration of the electronic device 1000 will be described in detail. Some of the components of the electronic device 1000 to be described later may be integrated and provided as one component, and one component may be provided separately as two or more components.

The electronic device 1000 may communicate with an external electronic device 2000 through a network (e.g., a near field communication network or a far field communication network). According to an embodiment, the electronic device 1000 may include the processor 1110, the memory 1120, the input module 1130, the display module 1140, a power module 1150, an internal module 1160, and an external module 1170. According to an embodiment, in the electronic device 1000, at least one of the above-described components may be omitted, or one or more other components may be added. According to an embodiment, some of the above-described components (e.g., the sensor module 1161, an antenna module 1162, or the sound output module 1163) may be integrated into another component (e.g., the display module 1140).

The processor 1110 may execute software to control at least one other component (e.g., a hardware or software component) of the electronic device 1000 coupled to the processor 1110, and may perform various data processing or computations. According to an embodiment, as at least part of data processing or computation, the processor 1110 may store instructions or data received from other components (e.g., the input module 1130, the sensor module 1161, or a communication module 1173) in a volatile memory 1121, process the instructions or the data stored in the volatile memory 1211, and store result data in the non-volatile memory 1122.

The processor 1110 may include a main processor 1111 and an auxiliary processor 1112. The main processor 1111 may include a central processing unit (CPU) 1111-1. The main processor 1111 may further include any one or more of a graphics processing unit 1111-2 (GPU), a communication processor (CP), and an image signal processor (ISP). The main processor 1111 may further include a neural processing unit (NPU) 111-3. The neural network processing unit 1111-3 is a processor specialized in processing an artificial intelligence model, and the artificial intelligence model may be generated through machine learning. The artificial intelligence model may include a plurality of artificial neural network layers. The artificial neural network may be one of a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-networks, or a combination of two or more of the above, but is not limited to the above examples. The artificial intelligence model may include, in addition to or as an alternative to, a software structure in addition to the hardware structure. At least two of the above-described processing units and processors may be implemented in one integrated configuration (e.g., a single chip), or each may be implemented in an independent configuration (e.g., a plurality of chips).

The auxiliary processor 1112 may include a controller 1112-1. The controller 1112-1 may include an interface conversion circuit and a timing control circuit. For example, the auxiliary processor 1112 may include the timing controller 150 illustrated in FIG. 1. At least some functions (or configurations) of the timing controller 150 may be included in the controller 1112-1, a data conversion circuit 1112-2, a gamma correction circuit 1112-3, a rendering circuit 1112-4, and the like.

The controller 1112-1 receives an image signal from the main processor 1111, converts a data format of the image signal to conform to an interface specification with the display module 1140, and outputs the image data. The controller 1112-1 may output various control signals supportive of driving the display module 1140.

The auxiliary processor 1112 may further include the data conversion circuit 1112-2, the gamma correction circuit 1112-3, the rendering circuit 1112-4, a touch control circuit 1112-5, and the like. The data conversion circuit 1112-2 may receive the image data from the controller 1112-1, and may compensate the image data such that an image is displayed with a desired luminance according to a characteristic of the electronic device 1000 or a user's setting, or may convert the image data to reduce power consumption or compensate for an afterimage.

The gamma correction circuit 1112-3 may convert the image data, a gamma reference voltage, or the like such that the image displayed on the electronic device 1000 has a desired gamma characteristic. The rendering circuit 1112-4 may receive the image data from the controller 1112-1 and render the image data in consideration of a pixel arrangement of the display panel 1141 applied to the electronic device 1000.

The touch control circuit 1112-5 may supply a touch signal to the input sensor 1161-2 and receive a sensing signal from the input sensor 1161-2 in response to the touch signal.

At least one among the data conversion circuit 1112-2, the gamma correction circuit 1112-3, the rendering circuit 1112-4, and the touch control circuit 1112-5 may be integrated into another component (e.g., the main processor 1111 or the controller 1112-1). At least one among the data conversion circuit 1112-2, the gamma correction circuit 1112-3, and the rendering circuit 1112-4 may be integrated into a source driver 1143 described herein.

The memory 1120 may store various data used by at least one component of the electronic device 1000 (e.g., the processor 1110 or the sensor module 1161) and input data or output data for instructions related to the various data. Various setting data corresponding to a user's setting may be stored in the memory 1120. The memory 1120 may include at least one among a volatile memory 1121 and a non-volatile memory 1122.

The input module 1130 may receive commands or data to be used for components of the electronic device 1000 (e.g., the processor 1110, the sensor module 1161, or the sound output module 1163) from outside the electronic device 1000, such as, for example, the user or the external electronic device 2000.

The input module 1130 may include a first input module 1131 to which a command or data is input from the user, and a second input module 1132 to which the command or the data is input from the external electronic device 2000. The first input module 1131 may include a microphone, a mouse, a keyboard, a key (e.g., a button), or a pen (e.g., a passive pen or an active pen). The second input module 1132 may support a designated protocol that may be connected to the external electronic device 2000 by wire or wirelessly. According to an embodiment, the second input module 1132 may include a high-definition multimedia interface (HDMI), a universal serial bus (USB) interface, an SD card interface, or an audio interface. The second input module 1132 may include a connector that may be physically connected to the external electronic device 2000, for example, an HDMI connector, a USB connector, an SD card connector, or an audio connector (e.g., a headphone connector).

The display module 1140 provides information to the user visually. The display module 1140 may include the display panel 1141, a gate driver 1142, a source driver 1143, and a voltage generation circuit 1144. The display module 1140 may further include a window, a chassis, and a bracket for protecting the display panel 1141. The display module 1140 may include at least some components of the display device 100 illustrated in FIG. 1.

The display panel 1141 (or display) may include a liquid crystal display panel, an organic light emitting display panel, or an inorganic light emitting display panel. The type of the display panel 1141 is not particularly limited. The display panel 1141 may be a rigid type or a flexible type capable of rolling or folding. The display module 1140 may further include a supporter, a bracket, a heat dissipation member, or the like that supports the display panel 1141. The display panel 1141 may include the display unit 110 illustrated in FIG. 1. For example, the display panel 1141 may include at least one pixel PX among the pixels PX illustrated in FIGS. 2 and 6 to 12.

The gate driver 1142 may be mounted on the display panel 1141 as a driving chip. The gate driver 1142 may be integrated into the display panel 1141. For example, the gate driver 1142 may include an ASG (Amorphous Silicon TFT Gate driver circuit), an LTPS (Low Temperature Polycrystalline Silicon) TFT gate driver circuit, or an OSG (Oxide Semiconductor TFT Gate driver circuit) internalized in the display panel 1141. The gate driver 1142 receives a control signal from the controller 1112-1 and outputs scan signals to the display panel 1141 in response to the control signal. The gate driver 1142 may include the scan driver 130 illustrated in FIG. 1.

The display module 1140 may further include a light emission driver. The light emission driver outputs a light emission control signal to the display panel 1141 in response to the control signal received from the controller 1112-1. The light emission driver may be formed such that the light emission driver is distinguished from the gate driver 1142 or may be integrated into the gate driver 1142. The light emission driver may include the light emission driver 140 illustrated in FIG. 1.

The source driver 1143 receives a control signal from the controller 1112-1, converts the image data into an analog voltage (e.g., a data signal) in response to the control signal, and then outputs the data signal to the display panel 1141. The source driver 1143 may include the data driver 120 illustrated in FIG. 1.

The source driver 1143 may be integrated into other components (e.g., controller 1112-1). The functions of the interface conversion circuit and the timing control circuit of the controller 1112-1 described herein may be integrated into the source driver 1143. The voltage generation circuit 1144 may output various voltages supportive of driving the display panel 1141. The voltage generation circuit 1144 may include the power supply 160 illustrated in FIG. 1.

In an embodiment, the source driver 1143 may convert data corresponding to a red (R), a green (G), and a blue (B) included in the image data received from the processor 1110 into a red data signal (or data voltage), a green data signal, and a blue data signal, and provide them to a plurality of pixel columns included in the display panel 1141 during one horizontal period.

The power module 1150 supplies power to the components of the electronic device 1000. The power module 1150 may include a battery that charges a power voltage. The battery may include a non-rechargeable primary battery, a rechargeable secondary battery, or a fuel cell. The power module 1150 may include a power management integrated circuit (PMIC). The PMIC supplies optimized power to each of the above-described module and a module to be described later. The power module 1150 may include a wireless power transmission/reception member electrically connected to the battery. The wireless power transmission/reception member may include a plurality of antenna radiators in the form of coils. In an embodiment, at least some configurations of the power module 1150 and the voltage generation circuit 1144 may be provided integrated into one. For example, the voltage generation circuit 1144 may be included in the power module 1150.

The electronic device 1000 may further include the internal module 1160 and the external module 1170. The internal module 1160 may include the sensor module 1161, the antenna module 1162, and the sound output module 1163. The external module 1170 may include a camera module 1171, a light module 1172, and a communication module 1173.

The sensor module 1161 may detect an input by the user's body or an input by a pen among the first input module 1131, and generate an electrical signal or a data value corresponding to the input. The sensor module 1161 may include at least one or more among a fingerprint sensor 1161-1, an input sensor 1161-2, and a digitizer 1161-3.

The fingerprint sensor 1161-1 may generate a data value corresponding to the user's fingerprint.

The input sensor 1161-2 may generate a data value corresponding to coordinate information of the input by a user's body or the input by a pen. The input sensor 1161-2 generates a capacitance change amount by the input as a data value. The input sensor 1161-2 may detect an input by a passive pen or transmit and receive data to and from an active pen.

The input sensor 1161-2 may measure a bio-signal such as, for example, blood pressure, moisture, or body fat. In an example in which the user contacts a part of the body with the sensor layer or the sensing panel and does not move for a certain period of time, based on a change in an electric field caused by the part of the body, the input sensor 1161-2 may sense the bio-signal and output information desired by the user to the display module 1140.

The digitizer 1161-3 may generate a data value corresponding to coordinate information of the input by the pen. The digitizer 1161-3 generates an electromagnetic change amount by the input as a data value. The digitizer 1161-3 may sense the input by the passive pen or transmit and receive data to and from the active pen.

At least one among the fingerprint sensor 1161-1, the input sensor 1161-2, and the digitizer 1161-3 may be implemented as a sensor layer formed on the display panel 1141 through a continuous process. At least one among the fingerprint sensor 1161-1, the input sensor 1161-2, and the digitizer 1161-3 may be disposed on an upper side of the display panel 1141, and any one among the fingerprint sensor 1161-1, the input sensor 1161-2, and the digitizer 1161-3, for example, the digitizer 1161-3 may be disposed under the display panel 1141.

At least two or more among the fingerprint sensor 1161-1, the input sensor 1161-2, and the digitizer 1161-3 may be formed to be integrated into one sensing panel through the same process. In the case of being integrated with the sensing panel, the sensing panel may be disposed between the display panel 1141 and a window disposed above the display panel 1141. According to an embodiment, the sensing panel may be disposed on the window, and the position of the sensing panel is not particularly limited.

At least one among the fingerprint sensor 1161-1, the input sensor 1161-2, and the digitizer 1161-3 may be embedded in the display panel 1141. That is, at least one among the fingerprint sensor 1161-1, the input sensor 1161-2, and the digitizer 1161-3 may be simultaneously formed through a process of forming elements (e.g., a light emitting element, a transistor, and the like) included in the display panel 1141.

The sensor module 1161 may generate an electrical signal or a data value corresponding to an internal state or an external state of the electronic device 1000. The sensor module 1161 may further include, for example, a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The antenna module 1162 may include one or more antennas for transmitting or receiving a signal or power to or from the outside. According to an embodiment, the communication module 1173 may transmit a signal to or receive a signal from an external electronic device through an antenna suitable for a communication method. The antenna pattern of the antenna module 1162 may be integrated into one configuration of the display module 1140 (e.g., the display panel 1141), the input sensor 1161-2, or the like.

The sound output module 1163 may be a device for outputting a sound signal to the outside of the electronic device 1000, and may include, for example, a speaker used for general purposes such as, for example, multimedia playback or recording playback, and a receiver used exclusively for phone reception. According to an embodiment, the receiver may be formed integrally with or separately from the speaker. A sound output pattern of the sound output module 1163 may be integrated with the display module 1140.

The camera module 1171 may capture a still image and a moving image. According to an embodiment, the camera module 1171 may include one or more lenses, an image sensor, or an image signal processor. The camera module 1171 may further include an infrared camera capable of measuring the presence or absence of a user, a position of the user, a gaze of the user, and the like.

The light module 1172 may provide light. The light module 1172 may include a light emitting diode or a xenon lamp. The light module 1172 may operate in conjunction with the camera module 1171 or may operate independently.

The communication module 1173 may support establishment of a wired or wireless communication channel between the electronic device 1000 and the external electronic device 2000, and communication through the established communication channel. The communication module 1173 may include one or both of a wireless communication module such as, for example, a cellular communication module, a near field communication module, or a global navigation satellite system (GNSS) communication module and a wired communication module such as, for example, a local area network (LAN) communication module or a power line communication module. The communication module 1173 may communicate with the external electronic device 2000 through a near field communication network such as, for example, Bluetooth, WiFi direct, or IrDA (infrared data association) or a cellular network, the Internet, or a long-range communication network such as, for example, a computer network (e.g., a LAN or a WAN). The various types of communication modules 1173 described herein may be implemented as one chip or may be implemented as separate chips.

The input module 1130, the sensor module 1161, the camera module 1171, and the like may be utilized to control the operation of the display module 1140 in conjunction with the processor 1110.

The processor 1110 outputs a command or data to the display module 1140, the sound output module 1163, the camera module 1171, or the light module 1172 based on the input data received from the input module 1130. For example, the processor 1110 may generate image data in response to input data applied through a mouse, an active pen, or the like and output the image data to the display module 1140, or may generate command data in response to the input data and output the command data to the camera module 1171 or the light module 1172. In a case in which input data is not received from the input module 1130, the processor 1110 may switch the operation mode of the electronic device 1000 to a low power mode or a sleep mode to reduce power consumed by the electronic device 1000.

The processor 1110 outputs a command or data to the display module 1140, the sound output module 1163, the camera module 1171, or the light module 1172 based on the sensing data received from the sensor module 1161. For example, the processor 1110 may compare the authentication data authorized by the fingerprint sensor 1161-1 with the authentication data stored in the memory 1120, and then execute an application according to the comparison result. The processor 1110 may execute a command or output corresponding image data to the display module 1140 based on the sensing data sensed by the input sensor 1161-2 or the digitizer 1161-3. In a case in which the sensor module 1161 includes a temperature sensor, the processor 1110 may receive temperature data for a measured temperature from the sensor module 1161, and further perform luminance correction or the like on the image data based on the temperature data.

The processor 1110 may receive measurement data on presence or absence of the user, a position of the user, and a gaze of the user from the camera module 1171. The processor 1110 may further perform luminance correction or the like on the image data based on the measurement data. For example, the processor 1110 that determines the presence or absence of the user through the input from the camera module 1171 may output the image data whose luminance is corrected to the display module 1140 through the data conversion circuit 1112-2 or the gamma correction circuit 1112-3.

Some of the above components may be connected to each other through a communication method between peripheral devices, for example, a bus, a general purpose input/output (GPI), a serial peripheral interface (SPI), a mobile industry processor interface (MIPI), or a Ultra path interconnect (UPI) link to exchange signals (e.g., commands or data) with each other. The processor 1110 may communicate with the display module 1140 through an interface promised to each other, for example, any one of the above-described communication schemes may be used, and is not limited to the communication scheme described herein.

FIGS. 14 to 17 are examples diagrams illustrating an electronic device according to various embodiments.

Referring to FIG. 14, a display device 100 according to an embodiment of the present disclosure may be applied to a smart glass. The smart glass may include a frame 111 and a lens unit 112. The smart glass is a wearable electronic device that may be worn on a user's face, and may have a structure in which a part of the frame 111 is folded or unfolded. For example, the smart glass may be a wearable device for augmented reality (AR).

The frame 111 may include a housing 111b supporting the lens unit 112 and a leg 111a for wearing by a user. The leg 111a may be connected to the housing 111b by a hinge and folded or unfolded.

A battery, a touch pad, a microphone, and/or a camera may be embedded in the frame 111. In some aspects, a projector that outputs light and/or a processor that controls an optical signal or the like may be embedded in the frame 111.

The lens unit 112 may be an optical member that transmits light or reflects light. The lens unit 112 may include glass and/or a transparent synthetic resin or the like.

The display device 100 according to an embodiment of the present disclosure may be applied to the lens unit 112. For example, the user may recognize an image displayed by an optical signal transmitted from a projector of the frame 111 through the lens unit 112. For example, the user may recognize information such as, for example, a time and a date displayed on the lens unit 112.

Referring to FIG. 15, a display device 100 according to an embodiment of the present disclosure may be applied to a head mounted display (HMD). The head mounted display may include a head mounting band 121 and a display housing case 122. For example, the head mounted display may be a wearable electronic device wearable on a user's head.

The head mounting band 121 may be connected to the display housing case 122 to fix the display housing case 122. The head mounting band 121 may include a horizontal band and a vertical band to secure the head mounted display to the user's head, the horizontal band may surround a side of the user's hair, and the vertical band may surround an upper portion of a user's hair. However, embodiments of the present disclosure are not necessarily limited thereto, and the head mounting band 121 may be implemented in the form of a spectacle frame or a helmet.

The display housing case 122 houses a display device and may include at least one lens. At least one lens may provide an image to a user. For example, the display device 100 according to an embodiment of the present disclosure may be applied to a left-eye lens and a right-eye lens implemented in the display housing case 122.

Referring to FIG. 16, a display device 100 according to an embodiment of the present disclosure may be applied to a smart watch. The smart watch may include a display unit 131 and a strap unit 133. The smart watch is a wearable electronic device, and the strap unit 133 may be mounted on a user's wrist. The display device 100 according to an embodiment of the present disclosure may be applied to the display unit 131. For example, the display unit 131 may provide image data including information such as, for example, time and date.

Referring to FIG. 17, a display device 100 according to an embodiment of the present disclosure may be applied to an automatic display. For example, the automatic display may refer to an electronic device provided inside and outside the vehicle and which provides image data.

For example, the display device 100 according to an embodiment of the present disclosure may be applied to at least one among an infotainment panel 141, a cluster 142, a co-driver display 143, a head-up display 144, a side mirror display 145, and a rear seat display 146 provided in a vehicle.

Although described herein with reference to embodiments of the present disclosure, it will be understood that those skilled in the art may variously modify and change the present disclosure without departing from the spirit and scope of the present disclosure described in the claims.

What is claimed is:

1. A pixel comprising:
a light emitting element positioned between a first power line and a second power line;
a first transistor connected to the first power line via a first node, connected to the second power line via a second node and the light emitting element, and having a gate electrode connected to a third node;
a second transistor connected between a data line and the first node and having a gate electrode connected to a scan line;
a third transistor connected between the second node and the third node and having a gate electrode connected to the scan line; and
a first capacitor having a first electrode connected to the first node and a second electrode connected to the second node.

2. The pixel of claim 1, further comprising:
a fourth transistor connected between the first power line and the first node and having a gate electrode connected to a light emission control line; and
a fifth transistor connected between the second node and an anode electrode of the light emitting element and having a gate electrode connected to the light emission control line.

3. The pixel of claim 2, wherein:
the second transistor and the third transistor are set to a turn-on state during a first period of a frame period, and
the fourth transistor and the fifth transistor are set to a turn-off state during the first period.

4. The pixel of claim 3, wherein the first period is a first horizontal period.

5. The pixel of claim 2, further comprising:
a second capacitor connected between the first power line and the third node.

6. The pixel of claim 2, further comprising:
a second capacitor connected between the first power line and the second node.

7. The pixel of claim 2, further comprising:
a second capacitor connected between the second node and the second power line.

8. The pixel of claim 2, further comprising:
a sixth transistor connected between the second electrode of the first capacitor and the second node and having a gate electrode connected to the scan line; and
a seventh transistor connected between the second electrode of the first capacitor and the second power line and having a gate electrode connected to the light emission control line.

9. The pixel of claim 8, further comprising:
a second capacitor connected between the first power line and the third node.

10. The pixel of claim 8, further comprising:
a second capacitor connected between the first power line and the second node.

11. The pixel of claim 8, further comprising:
a second capacitor connected between the second node and the second power line.

12. A display device comprising:
pixels connected to scan lines, data lines, and light emission control lines;
a scan driver which drives the scan lines;
a light emission driver which drives the light emission control lines; and
a data driver which drives the data lines,
wherein a pixel among the pixels comprises:
a light emitting element positioned between a first power line and a second power line;
a first transistor connected to the first power line via a first node, connected to the second power line via a second node and the light emitting element, and having a gate electrode connected to a third node;
a second transistor connected between a data line among the data lines and the first node and having a gate electrode connected to a scan line among the scan lines;
a third transistor connected between the second node and the third node and having a gate electrode connected to the scan line; and
a first capacitor having a first electrode connected to the first node and a second electrode connected to the second node.

13. The display device of claim 12, wherein the pixel further comprises:
a fourth transistor connected between the first power line and the first node and having a gate electrode connected to a light emission control line among the light emission control lines; and
a fifth transistor connected between the second node and an anode electrode of the light emitting element and having a gate electrode connected to the light emission control line.

14. The display device of claim 13, wherein:
the scan driver supplies an enable scan signal to the scan line such that the second transistor and the third transistor are turned on during a first period of a frame period, and
the light emission driver supplies a disable light emission control signal to the light emission control line such that the fourth transistor and the fifth transistor are turned off during the first period.

15. The display device of claim 14, wherein:
the first period is a first horizontal period; and
the data driver supplies a data signal to the data line during the first period.

16. The display device of claim 13, wherein the pixel further comprises a second capacitor connected between the first power line and the third node.

17. The display device of claim 13, wherein the pixel further comprises a second capacitor connected between the first power line and the second node.

18. The display device of claim 13, wherein the pixel further comprises a second capacitor connected between the second node and the second power line.

19. The display device of claim 13, wherein the pixel further comprises:
a sixth transistor connected between the second electrode of the first capacitor and the second node and having a gate electrode connected to the scan line; and
a seventh transistor connected between the second electrode of the first capacitor and the second power line having a gate electrode connected to the light emission control line.

20. An electronic device comprising:
a processor; and
a display module which displays an image based on image data supplied from the processor,
wherein:
the display module comprises pixels, and
at least one pixel among the pixels comprises:
a light emitting element positioned between a first power line and a second power line;
a first transistor connected to the first power line via a first node, connected to the second power line via a second node and the light emitting element, and having a gate electrode connected to a third node;
a second transistor connected between a data line among data lines and the first node and having a gate electrode connected to a scan line among scan lines;
a third transistor connected between the second node and the third node and having a gate electrode connected to the scan line; and
a first capacitor having a first electrode connected to the first node and a second electrode connected to the second node.
